(19) United States
(12) Patent Application Publication
(10) Pub. No.: US 2004/0140499 A1
(43) Pub. Date: Jul. 22, 2004

(54) Method of manufacturing a semiconductor device

(76) Inventors: Kazuo Sato, Ome (JP); Naoto Fujiki, Tachikawa (JP)

Correspondence Address: Mattingly, Stanger & Malur, P.C., Suite 370, 1800 Diagonal Road, Alexandria, VA, 22314, US

(21) Appl. No.: 10/739,116

(22) Filed: Dec. 19, 2003

(30) Foreign Application Priority Data
Dec. 25, 2002 (JP) P2002-374121

(51) Int. Cl. H01L 29/788

(52) U.S. Cl. 257/316

(57) ABSTRACT

The present invention is to prevent electrostatic breakdown or drying failure in a step of cleaning a backside of a semiconductor wafer, thereby improving reliability of a semiconductor device. A semiconductor wafer is rotated in a state where a backside of the semiconductor wafer is directed upward. A rinsing liquid is supplied to the backside of the semiconductor wafer from a nozzle to clean the same by a brush. During that time, a rinsing liquid is supplied to a surface of the semiconductor wafer from a nozzle disposed below that. At that time, a direction of spray of the rising liquid from the nozzle is set to be orthogonal to the surface of the semiconductor wafer, and a liquid flow of the rinsing liquid sprayed from the nozzle is applied to a position away from the center of the surface of the semiconductor wafer.

### TECHNICAL FIELD OF THE INVENTION

The present invention relates to a technique of manufacturing a semiconductor device, particularly to a technique effective to be applied to a technique of manufacturing a semiconductor device having a step of cleaning a backside of a semiconductor wafer.

### BACKGROUND OF THE INVENTION

The Japanese Patent Application Laid-Open Publication No. 10-154679 describes a technique where ultrasonic wave cleaning is performed while directing a backside of a substrate upward, a cleaning liquid is supplied to an edge of a surface of the substrate via a diffusion plate from a nozzle below the surface of the substrate in an oblique direction, and a film made of the cleaning liquid is formed on the surface of the substrate in a hollow manner.

The Japanese Patent Application Laid-Open Publication No. 9-246224 describes a technique of cleaning a surface of a wafer by a shower nozzle while directing the same upward, and supplying a cleaning liquid from the nozzle disposed below a backside of the wafer in an oblique direction to clean the wafer.

The Japanese Patent Application Laid-Open Publication No. 2002-57138 describes a technique of cleaning a surface of a substrate while directing the same upward, and supplying pure water from a pure water nozzle disposed below a backside of the substrate in an oblique direction.

The Japanese Patent Application Laid-Open Publication No. 10-308374 describes a technique of moving a nozzle for supplying a cleaning liquid on an upper surface of a semiconductor wafer.

### SUMMARY OF THE INVENTION

In a step of manufacturing a semiconductor device, contamination such as particles may be attached to a semiconductor wafer when transferring in various steps or between steps. When various steps are performed in a state where contamination is attached, the semiconductor wafer may be contaminated so that reliability of the semiconductor device to be manufactured will be lowered. Therefore, it is required that the contamination attached to the semiconductor wafer be removed by cleaning.

According to the investigation by the present inventors, it is found that, in a cleaning step of removing particles attached to a backside of a semiconductor wafer while directing the same upward, when a cleaning liquid sprayed from a nozzle disposed below a surface of the semiconductor wafer is applied to the same position on the surface of the semiconductor wafer for a long time, the position is charged due to static electricity and electrostatic breakdown occurs. Further, it is found that if dripping occurs to the nozzle when supplying the cleaning liquid to the surface of the semiconductor wafer from the nozzle disposed below the surface of the semiconductor wafer is stopped, the dripping is reflected by a rotation plate for rotating the semiconductor wafer when drying the semiconductor wafer and is reattached to the surface of the semiconductor wafer so that drying failure is caused and water mark occurs. The water mark on the surface of the semiconductor wafer may cause machining failure in the subsequent steps. This fact lowers reliability of the semiconductor device to be manufacture and reduces manufacturing yield of the semiconductor device.

In a method of cleaning a backside of a wafer (substrate) while directing the same upward and supplying a cleaning liquid to an edge of a surface of the wafer via a diffusion plate from a nozzle below the surface of the wafer in an oblique direction, at a stage where supplying the cleaning liquid to the surface of the wafer is stopped, dripping occurs to the nozzle or the diffusion plate, and the dripped water may be reattached to the surface of the wafer at the drying stage, which will cause water mark in the wafer. This fact causes machining failure and reduces reliability or manufacturing yield of the semiconductor device to be manufactured.

In a method of cleaning a surface of a wafer (substrate) while directing the same upward and supplying a cleaning liquid (pure water) from a nozzle disposed below a backside of the wafer in an oblique direction, at a stage where supplying the pure water to the backside of the wafer is stopped, dripping occurs to the nozzle for supplying a cleaning liquid, and the dripped water may be reattached to the wafer at the drying stage so that water mark will occur. This fact causes machining failure and reduces reliability or manufacturing yield of the semiconductor device to be manufacture. In a method of cleaning the surface of the wafer, even when static electricity occurs to the backside at the opposite side of the wafer, the backside is not a device (semiconductor device) forming surface so that no problem is caused. But when cleaning the backside of the wafer, if static electricity occurs to the surface which is a device forming surface, there is another problem that the device is broken due to the static electricity.

In a method of supplying a cleaning liquid to an upper surface of a semiconductor wafer, water dripped from a nozzle may be reattached to the wafer at the drying stage and the water mark will occur. This fact causes machining failure and reduces reliability or manufacturing yield of the semiconductor device to be manufactured.

An object of the present invention is to provide a method of manufacturing a semiconductor device capable of improving reliability of the semiconductor device.

Another object of the present invention is to provide a method of manufacturing a semiconductor device capable of improving manufacturing yield of the semiconductor device.

The above and other objects and novel features of the present invention will be apparent from the description and the accompanying drawing of the present specification.

The outlines of representative inventions among the inventions disclosed in this application will be simply described as follows.

A method of manufacturing a semiconductor device according to the present invention is directed for, when cleaning a backside of a semiconductor wafer, supplying a rinsing liquid to a position away from the center of a surface of the semiconductor wafer.

Further, a method of manufacturing a semiconductor device according to the present invention is directed for, when cleaning a backside of a semiconductor wafer, setting a direction of spray of a rinsing liquid from rinsing liquid supplying means for supplying the rinsing liquid to a surface of the semiconductor wafer to be orthogonal to the surface of the semiconductor wafer.

### BRIEF DESCRIPTIONS OF THE DRAWINGS

FIG. 1 is a section view of essential part in a step of manufacturing a semiconductor device according to one embodiment of the present invention;

FIG. 2 is a section view of essential part in the step of manufacturing a semiconductor device subsequent to FIG. 1;

FIG. 3 is a section view of essential part in the step of manufacturing a semiconductor device subsequent to FIG. 2;

FIG. 4 is a flow chart for explaining steps from ion implantation to thermal diffusion;

FIG. 5 is a flow chart for explaining steps from ion implantation to thermal diffusion;

FIG. 6 is a section view of essential part in the step of manufacturing a semiconductor device subsequent to FIG. 3;

FIG. 7 is a section view of essential part in the step of manufacturing a semiconductor device subsequent to FIG. 6;

FIG. 8 is a section view of essential part in the step of manufacturing a semiconductor device subsequent to FIG. 7;

FIG. 9 is an explanatory diagram showing a schematic structure of a cleaning device used in a step of cleaning a backside of a semiconductor wafer;

FIG. 10 is an explanatory diagram showing a processing sequence of the step of cleaning a backside of a semiconductor wafer;

FIG. 11 is an explanatory diagram showing a conceptual structure of a cleaning unit of the cleaning device for cleaning a backside of a semiconductor wafer;

FIG. 12 is a graph showing a processing sequence of a semiconductor wafer;

FIG. 13 is an explanatory diagram of electrostatic breakdown caused by a backside rinsing processing in the step of cleaning a backside of a semiconductor wafer;

FIG. 14 is a partially enlarged diagram of an area in the vicinity of a nozzle for backside rinsing processing in the cleaning unit in FIG. 11;

FIG. 15 is a top view of the nozzle for backside rinsing processing;

FIG. 16 is a plan view for explaining a position on a surface of a semiconductor wafer on which a liquid flow of a rinsing liquid sprayed from a nozzle is fallen;

FIG. 17 is a plan view for explaining a position on a surface of a semiconductor wafer on which a liquid flow of a rinsing liquid sprayed from a nozzle is fallen;

FIG. 18 is an explanatory diagram for a nozzle for backside rinsing processing according to another embodiment; and

FIG. 19 is a flow chart for explaining steps from ion implantation to thermal diffusion.

### DESCRIPTION OF THE PREFERRED EMBODIMENTS

Prior to describing the present application in detail, the meanings of the terms in this application will be explained as follows.

1. When referring to a name of material such as silicon, the name does not indicate only the shown material, but includes material which contains the shown material (element, atom group, molecular, polymer molecule, copolymer, compound) as a main component or composition component, except when clearly denoted.

In other words, a silicon area includes a pure silicon area, an area whose main component is silicon where impurities are doped, a mix crystal area whose main element is silicon such as GeSi, and the like, except when clearly denoted to the contrary. Further, “M” in MIS is not limited to pure metal, and includes a polysilicon (containing amorphous) electrode, a silicide layer, and other member indicating the nature similar to a metal, except when clearly denoted to the contrary. Furthermore, “I” in MIS is not limited to an oxide film such as a silicon oxide film, and includes a nitride film, an oxynitriding film, an alumina film, other typical electric film, a high dielectric film, a ferroelectric film, and the like, except when clearly denoted to the contrary.

2. Wafer refers to a semiconductor monocrystal substrate such as silicon used for manufacturing a semiconductor integrated circuit (generally, substantially circular, a semiconductor wafer, a semiconductor chip which is divided into unit integrated circuit areas, or pellet, as well as a base area thereof), a sapphire substrate, a glass substrate, other insulator, semi-insulator or semiconductor substrate, as well as a complex substrate thereof.

3. A direction orthogonal to one surface includes not only a case where an angle between both surfaces completely matches to 90 degrees but also a state slightly tilted from 90 degrees.

In the following embodiments, a description will be given by dividing into a plurality of sections or embodiments as needed, but they are not independent of each other, and they are in a relationship where one is part or the whole of variation, details, supplementary explanation, and the like of the other except when clearly denoted.

Further, in the following embodiments, when referring to the number of elements (including quantity, numeric value, amount, range, and the like), the number is not limited to the specific number, and may be not less than or not more than the specific number except when clearly denoted and clearly limited to the specific number in principle.

Further, in the following embodiments, it goes without saying that the constructing elements (including element steps and the like) are not necessarily indispensable except when clearly denoted and clearly considered to be indispensable.

Similarly, in the following embodiments, when referring to a shape, a positional relationship, and the like of the constructing elements, one substantially close or similar to the shape is included except when clearly denoted and considered to be apparently different in principle. This is applied to the numeric value and the range.

Throughout all the drawings for explaining the embodiments, like references are denoted to like parts having the same function, and a repeated description will be omitted.

As for the drawings used in the present embodiment, even plan views may be denoted with hutching in order to make the drawings obvious. Further, hutching may be omitted even in section views.

Hereinafter, the embodiments according to the present invention will be described in detail with reference to the drawings.

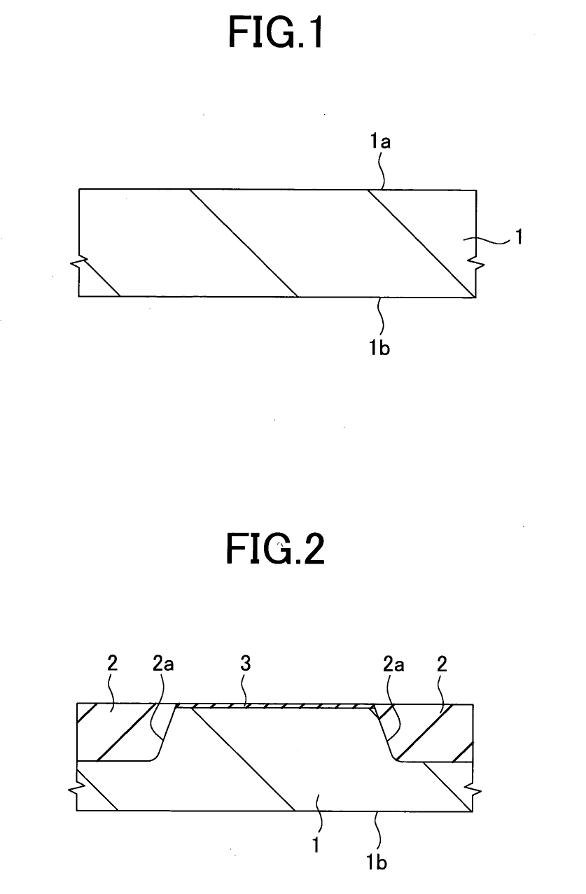

FIGS. 1 to 3 are section views of essential parts in steps of manufacturing a semiconductor device, for example, a MISFET (Metal Insulator Semiconductor Field Effect Transistor) according to one embodiment of the present invention, respectively.

As shown in FIG. 1, there is prepared a semiconductor wafer (wafer, semiconductor substrate) 1 which is comprised of p-type monocrystal silicon having specific resistance of, for example, about 1 to 10 Ω cm. The semiconductor wafer 1 has two main surfaces, that is, a surface 1a which is a main surface at a semiconductor device forming side and a backside 1b which is a main surface contrary (opposite) to the surface 1a.

As shown in FIG. 2, an isolation area 2 is formed on the surface (main surface at the semiconductor device forming side) 1a of the semiconductor wafer 1. The isolation area 2 is comprised of silicon oxide, and can be made by a STI (Shallow Trench Isolation, or SGI: Shallow Groove Isolation) method or a LOCOS (Local Oxidization of Silicon) method, for example. In FIG. 2, the isolation area 2 is comprised of silicon oxide which embeds an isolation trench 2a formed in the surface 1a of the semiconductor wafer 1. The isolation area 2 functions to separate respective devices (semiconductor devices, for example MISFET) formed on the semiconductor wafer 1. Thereby, an electric interference between formed devices is eliminated so that the respective devices can be independently controlled. Further, a thin dielectric film 3 is formed in an area (semiconductor device forming area) between the isolation areas 2 on the surface 1a of the semiconductor wafer 1. This dielectric film 3 is comprised of, for example, a silicon oxide film, and can be made when forming the isolation area 2 by the STI method or the LOCOS method. Alternatively, the dielectric film 3 can be made after the isolation area 2 is formed. The dielectric film 3 can function to protect the surface 1a of the semiconductor wafer 1 at the time of ion implantation (ion implantation for forming a well area) described later.

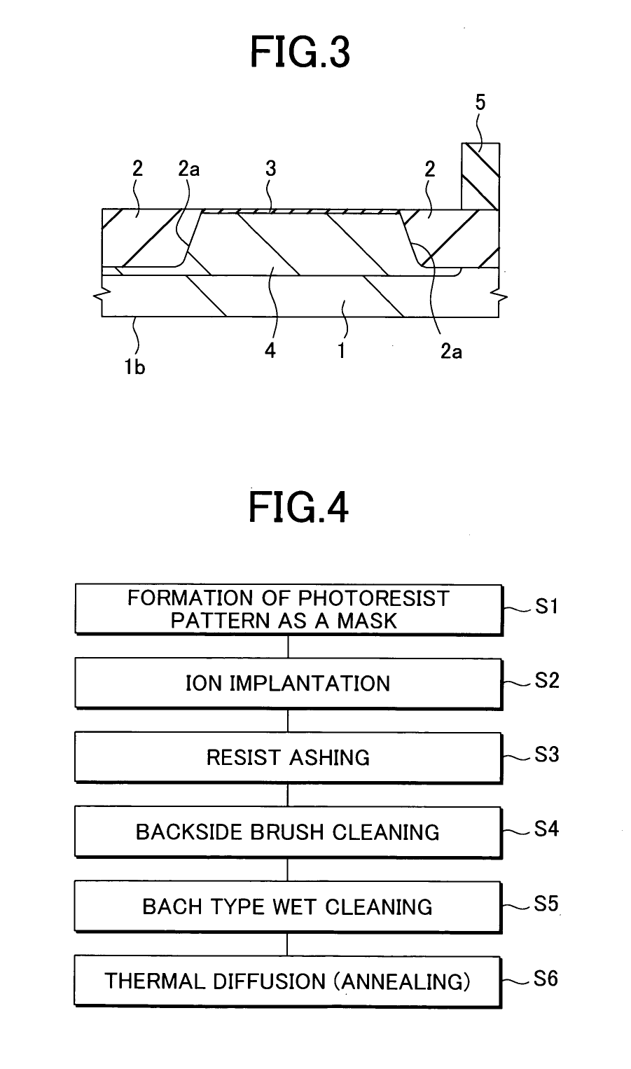

Next, as shown in FIG. 3, p-type impurities such as boron (B) are ion-implanted into an area where an n-channel MISFET is formed on the semiconductor wafer 1 to form a p-type well 4. When performing ion implantation, a photo lithograph pattern (photo resist pattern, photo resist mask) 5 which covers an area where impurities are not introduced is formed on the surface of the semiconductor wafer 1 by using a photo lithography method, ion implantation using the photo lithograph pattern 5 as a mask is performed, and the p-type impurities are introduced into only an area where the p-type well 4 should be formed. After the photo lithograph pattern 5 is removed by ashing processing, thermal diffusion is performed for diffusing or activating the impurities introduced (ion-implanted) into the p-type well 4. Thereby, the p-type well 4 is completed.

When performing this thermal diffusion, if contamination such as particles is attached on the semiconductor wafer 1, the contamination may be diffused into the semiconductor wafer 1 and performance or reliability of a semiconductor device to be formed thereafter will be decreased. Therefore, the semiconductor wafer 1 is cleaned before the thermal diffusion so that the contamination such as particles is removed.

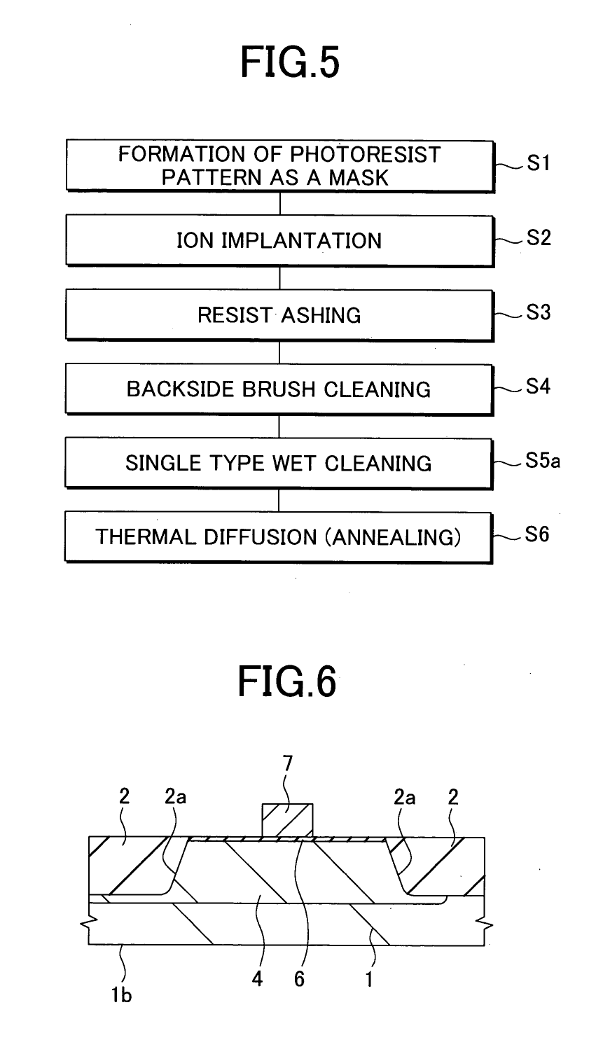

FIG. 4 and FIG. 5 are flow charts for explaining steps from ion implantation to thermal diffusion for forming the p-type well 4. As shown in FIG. 4, the photo lithograph pattern (photo resist mask) 5 is formed (step S1), and ion implantation is performed by using the photo lithograph pattern 5 as a mask (step S2). Then, the photo lithograph pattern 5 is removed by the ashing processing (step S3). Brush cleaning described later in detail is performed for the backside 1b of the semiconductor wafer 1 (step S4). Thereafter, the semiconductor wafer 1 is wet-cleaned by a butch type wet-cleaning device (step S5). Then, thermal diffusion is performed to diffuse or activate the impurities introduced (ion-implanted) into the semiconductor wafer 1 (step S6). As other form, as shown in FIG. 5, it is also possible that after the backside 1b of the semiconductor wafer 1 is brush-cleaned (step S4), the semiconductor wafer 1 is wet-cleaned by a single wafer type wet-cleaning device (step 5a) and then thermal diffusion is performed to diffuse or activate the impurities introduced into the semiconductor wafer 1 (step S6).

FIGS. 6 to 8 are section views of essential parts in the steps of manufacturing a semiconductor device subsequent to FIG. 3, respectively. After the p-type well 4 is formed as described above (after the thermal diffusion in step S6), the dielectric film 3 is removed, and then a clean gate dielectric film 6 is formed on the surface of the cleaned p-type well 4 as shown in FIG. 6. The gate dielectric film 6 is comprised of, for example, a thin silicon oxide film, and can be made by a thermal oxidization method.

Next, a gate electrode 7 is formed on the gate dielectric film 6 of the p-type well 4. For example, a polycrystal silicon film is formed over the surface 1a of the semiconductor wafer 1, phosphorous (P) is ion-implanted into the polycrystal silicon film to form an n-type semiconductor film having low resistance, and the polycrystal silicon film is patterned by dry etching, so that the gate electrode 7 comprised of the polycrystal silicon film can be formed.

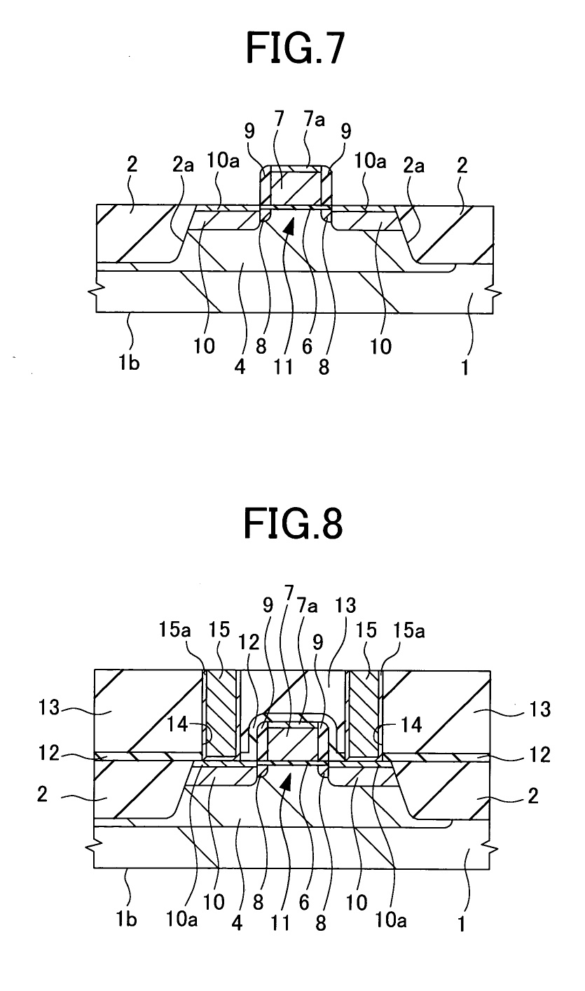

Next, as shown in FIG. 7, n-type impurities such as phosphorous are ion-implanted into areas at both sides of the gate electrode 7 of the p-type well 4 so that n⁻-type areas 8 are formed.

Next, side-wall spacers or side-walls 9 comprised of, for example, silicon oxide are formed on the side-walls of the gate electrode 7. The side-wall 9 can be formed by depositing a silicon oxide film over the semiconductor wafer 1 and anisotropically etching this silicon oxide film, for example.

After the side-walls 9 are formed, n⁺-type areas 10 (source/drain) are formed by ion-implanting n-type impurities such as phosphorous (P) into the areas at both sides of the gate electrode 7 and the side-walls 9 of the p-type well 4. An impurity concentration in the n⁺-type area 10 is higher than in the n⁻-type area 8.

Next, the surfaces of the gate electrode 7 and the n⁺-type areas 10 are exposed and for example a cobalt (Co) film is deposited to perform thermal diffusion, so that a silicide film 7a and a silicide film 10a are formed on the respective surfaces of the gate electrode 7 and the n⁺-type areas 10. Thereby, a diffusion resistance of the n⁺-type areas 10 and a contact resistance can be lowered. Thereafter, an unreacted cobalt film is removed.

In this manner, an n-channel MISFET (Metal Insulator Semiconductor Field Effect Transistor) 11 is formed on the p-type well 4.

Next, as shown in FIG. 8, a dielectric film 12 comprised of silicon nitride and a dielectric film 13 comprised of silicon oxide are sequentially deposited over the semiconductor wafer 1. Then, the dielectric film 13 and the dielectric film 12 are sequentially dry-etched so that contact holes 14 are formed above the n⁺-type areas (source/drain) 10 and the like. At the bottom of the contact holes 14, part of the main surface of the semiconductor wafer 1, for example, part of the n⁺-type areas 10 (silicide film 10a) or part of the gate electrode 7 (silicide film 7a) is exposed.

Next, a plug 15 comprised of tungsten (W) is formed inside the contact hole 14. The plug 15 can be formed by forming a TiN film 15a as a barrier film on the dielectric film 13 including the inside of the contact hole 14, and then forming a tungsten film on the TiN film 15a by a CVD (Chemical Vapor Deposition) method so as to embed the contact hole 14 and removing the unnecessary tungsten film and the TiN film 15a on the dielectric film 13 by a CMP (Chemical Mechanical Polishing) method, an etch-back method.

Thereafter, a wiring layer to be electrically connected to the plug 15 is formed, but illustration and description thereof will be omitted here.

Next, a step (step S4) of cleaning (brush-cleaning) the backside 1b of the semiconductor wafer 1 performed in the present embodiment will be described.

As described above, after ion implantation is performed by using the photo lithograph pattern 5 as a mask and impurities are introduced into the semiconductor wafer 1, the photo lithograph pattern 5 is removed by ashing, and then thermal diffusion is performed to diffuse or activate the impurities introduced into the semiconductor wafer 1. At this time, after the photo lithograph pattern 5 is removed by the ashing processing as described above, the semiconductor wafer 1 is cleaned before performing the thermal diffusion for diffusing the impurities. Thereby, contamination such as particles or metal impurities attached on the semiconductor wafer 1 is removed.

The contamination attached on the semiconductor wafer 1 can be removed by wet-cleaning (step S5 or step S5a) using, for example, an APM (Ammonia-Hydrogen Peroxide Mixture) liquid, a DHF (Diluted Hydrofluoric acid) liquid, a HPM (Hydrochloric acid-Hydrogen Peroxide Mixture) liquid, but the particles attached on the backside 1b of the semiconductor wafer 1 due to absorption at the time of transferring between steps or in each step has strong adhesion so that they are difficult to sufficiently remove only by the wet-cleaning. If particles, for example, particles containing metal remain on the backside 1b of the semiconductor wafer 1, they may be diffused into the semiconductor wafer 1 by the thermal diffusion (step S6) after the cleaning processing and degradation of carrier lifetime or crystal default may be caused. This fact has a possibility that performance or reliability of a semiconductor device to be manufactured is lowered.

In the present embodiment, prior to the wet-cleaning processing (step S5 or step S5a), the backside of the semiconductor wafer 1 is mechanically cleaned by a brush (step S4) so that particles attached on the backside 1b of the semiconductor wafer 1 are removed.

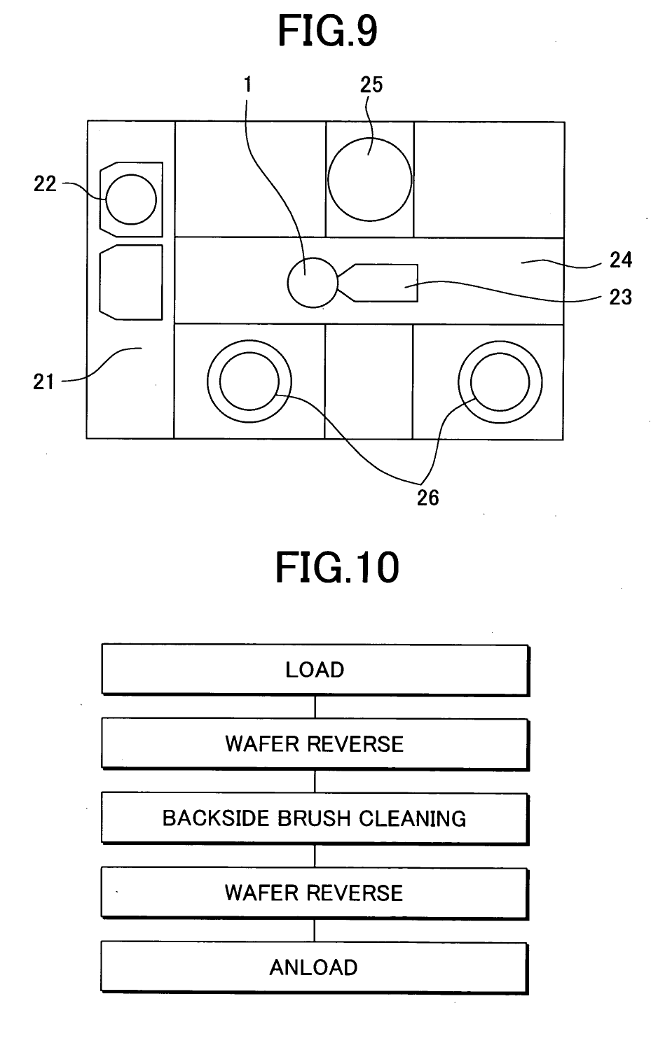

FIG. 9 is an explanatory diagram (plan view) showing a schematic structure of a cleaning device used in the step (step S4) of cleaning the backside 1b of the semiconductor wafer 1 performed in the present embodiment. FIG. 10 is an explanatory diagram showing a processing sequence (flow) of the step of cleaning the backside 1b of the semiconductor wafer 1.

As shown in FIG. 9 and FIG. 10, the semiconductor wafer 1 is mounted or accommodated in a cassette case 22 placed on a load/unload portion (load/unload stage) 21 (step S11), and is fetched therefrom to be transferred to a wafer reverse room 25 via a transfer lane 24 by using a transfer system (transfer device) 23. The semiconductor wafer 1 transferred to the wafer reverse room 25 is reversed by using a reverse system (not shown) (step S12). Thereby, the backside 1b of the semiconductor wafer 1 is directed upward. The reversed semiconductor wafer 1 is transferred to a cleaning unit (wafer backside cleaning unit, processing unit) 26 by the transfer system 23, where the backside 1b of the semiconductor wafer 1 is brush-cleaned (step S13). After the brush-cleaning, the semiconductor wafer 1 is transferred to the wafer reverse room 25 by the transfer system 23 to be reversed by using the reverse system (not shown) (step S14). Thereby, the surface 1a of the semiconductor wafer 1 is directed upward. Thereafter, the semiconductor wafer 1 is transferred to the cassette case 22 placed on the load/unload portion 21 to be accommodated into the cassette case 22 again (step S15).

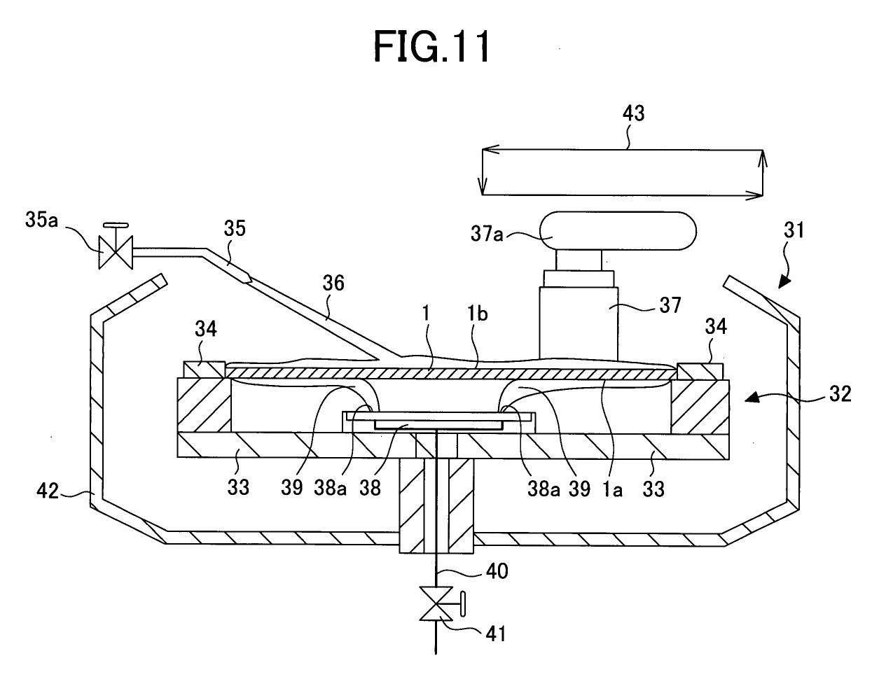

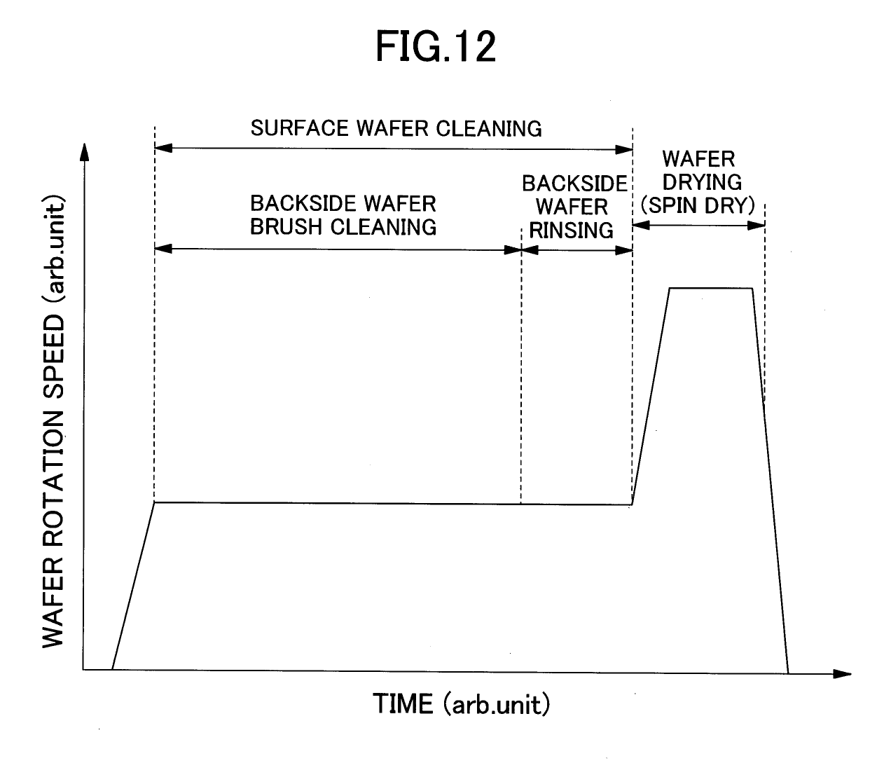

FIG. 11 is an explanatory diagram (longitudinal section view) showing a conceptual structure of the cleaning unit of the cleaning device for cleaning (brush-cleaning) the backside 1b of the semiconductor wafer 1. The cleaning unit 31 of the cleaning device in FIG. 11 corresponds to the cleaning unit 26 in FIG. 9. Further, FIG. 12 is a graph showing a processing sequence of the semiconductor wafer 1 in the step of cleaning the backside 1b of the semiconductor wafer 1. The horizontal axis in the graph of FIG. 12 corresponds to an elapsed time (arbitrary unit), and the vertical axis in the graph corresponds to a rotation frequency or rotation speed (arbitrary unit) per unit time of the semiconductor wafer 1.

As shown in FIG. 11, the semiconductor wafer 1 transferred to the cleaning unit 31 is held by a spin chuck 32. The spin chuck 32 has a spin table 33 and a wafer chuck 34 fixed and connected to the outer periphery of the spin table 33. The spin table 33 is a rotation plate which is constructed to be rotatable at high speed by a rotation system (for example, motor) (not shown), and has a larger diameter than the semiconductor wafer 1, for example. The wafer chuck 34 is constructed so as to hold the semiconductor wafer 1, thereby the semiconductor wafer 1 is held such that the backside 1b of the semiconductor wafer 1 to be cleaned is directed upward and the surface (main surface at the semiconductor device forming side) 1a is directed downward. Therefore, the spin chuck 32 is constructed to rotate the semiconductor wafer 1. In other words, the spin table 33 is rotated by the rotation system (not shown) so that both the wafer chuck 34 and the semiconductor wafer 1 held on the wafer chuck 34 can be rotated.

A nozzle (rinse nozzle, rinsing liquid supplying means) 35 is disposed above (obliquely upward) the outer periphery of the backside 1b of the semiconductor wafer 1, and is constructed such that a rinsing liquid (cleaning liquid) 36 is sprayed (ejected) from the nozzle 35 toward the backside 1b of the semiconductor wafer 1 and the rinsing liquid 36 can be supplied to the backside 1b of the semiconductor wafer 1. The rinsing liquid 36 may employ pure water, for example. Further, there is constructed such that the supply (eject) amount of the rinsing liquid 36 can be adjusted by a valve 35a (or supply start/stop of the rinsing liquid 36 can be changed over).

A brush 37 for cleaning the backside 1b of the semiconductor wafer 1 is disposed above (obliquely upward) other outer periphery of the backside 1b of the semiconductor wafer 1. The brush 37 is held by a brush arm 37a, and is constructed to perform operations (horizontal movement and vertical movement) described later.

A nozzle (backside rinse nozzle, rinsing liquid supplying means) 38 is disposed below the backside 1b of the semiconductor wafer 1, and is constructed such that a rinsing liquid (backside rinsing liquid, cleaning liquid) 39 as a backside rinsing liquid is sprayed (ejected, supplied) from the nozzle 38 toward the surface 1a of the semiconductor wafer 1 and the rinsing liquid (backside rinsing liquid) 39 can be supplied to the surface 1a of the semiconductor wafer 1. The rinsing liquid 39 may employ pure water, for example. The nozzle 38 is provided with a port (rinse port, rinsing liquid spray port) 38a for spraying the rinsing liquid 39, and the rinsing liquid 39 can be sprayed from the port 38a of the nozzle 38 toward the surface 1a of the semiconductor wafer 1. The rinsing liquid 39 is supplied to the nozzle 38 through a piping (backside rinse piping) 40 to be sprayed from the port 38a of the nozzle 38. Further, there is constructed such that the supply (spray) amount of the rinsing liquid 39 can be adjusted by a valve 41 (or supply start/stop of the rinsing liquid 39 can be changed over). The nozzle 38 and the piping 40 are not fixed on the spin table 33, and there is constructed such that even when the spin table 33 is rotated, the nozzle 38 and the piping 40 are not rotated.

A splash guard 42 is disposed around the spin chuck 32, and is constructed such that the rinsing liquid 36 or the rinsing liquid 39 is prevented from splashing. The rinsing liquid 36 and the rinsing liquid 39 supplied from the nozzle 35 and the nozzle 38 to the backside 1b and the surface 1a of the semiconductor wafer 1 can be stored at the lower portion of the splash guard 42 to be finally discharged by a drain system (not shown).

In order to clean the backside 1b of the semiconductor wafer 1, the semiconductor wafer 1 held on the wafer chuck 34 (spin chuck 32) as shown in FIG. 11 is first rotated at a predetermined rotation speed as shown in the graph of FIG. 12. The rotation speed of the semiconductor wafer 1 at this time is about 1000 rpm to 2000 rpm (1000 rotations/minute to 2000 rotations/minute), for example. The semiconductor wafer 1 can be rotated by rotating the spin table 33 (spin chuck 32). At the substantially same time with the rotation processing of the semiconductor wafer 1, the rinsing liquid 36 is sprayed (ejected) from the nozzle 35 disposed obliquely upward the backside 1b of the semiconductor wafer 1 toward the backside 1b of the semiconductor wafer 1 so that supplying the rinsing liquid 36 toward the backside 1b of the semiconductor wafer 1 is started.

At the substantially same time with the rotation of the semiconductor wafer 1 or the supply start of the rinsing liquid 36, the brush 37 is horizontally moved from the position obliquely upward the backside 1b of the semiconductor wafer 1 toward above the center position of the backside 1b of the semiconductor wafer 1 by the brush arm 37a. The brush 37 which reaches above the substantially center position of the backside 1b of the semiconductor wafer 1 descends toward the semiconductor wafer 1. The descending is stopped at the position where the brush 37 contacts the backside 1b of the semiconductor wafer 1. Then, the brush 37 is peripherally (horizontally) moved from the center of the backside 1b of the semiconductor wafer 1. Since the semiconductor wafer 1 is rotating, the entire backside 1b of the semiconductor wafer 1 is contacted on the brush 37. Thereby, the entire backside 1b of the semiconductor wafer 1 is cleaned (brush-cleaned, scrub-cleaned) so that particles attached on the backside 1b of the semiconductor wafer 1 are mechanically removed.

The backside 1b of the semiconductor wafer 1 can be cleaned while rotating not only the semiconductor wafer 1 but also the brush 37, but the backside 1b of the semiconductor wafer 1 can be cleaned without rotating the brush 37 since the semiconductor wafer 1 is rotating. When the brush 37 is rotated, high cleaning performance can be obtained. When the brush 37 is not rotated, it is not required to provide a rotation system of the brush 37, thereby reducing the size of the cleaning device (cleaning unit).

After the brush 37 is moved in a direction of outer periphery of the semiconductor wafer 1 and cleaning is performed from the center of the backside 1b of the semiconductor wafer 1 to the outer periphery, the brush 37 ascends and is separated from the backside 1b of the semiconductor wafer 1. Then, the brush 37 is horizontally moved toward the center of the backside 1b of the semiconductor wafer 1 again, descends toward the semiconductor wafer 1 at the stage where it reaches above the substantially center position of the backside 1b of the semiconductor wafer 1, is moved in a direction of outer periphery of the semiconductor wafer 1 in a state where the backside of the semiconductor wafer 1 is contacted, and the cleaning operation of the backside 1b of the semiconductor wafer 1 is repeated. FIG. 11 schematically shows a movement of brush 43 of the brush 37 by the brush arm 37a. This operation (movement of brush 43) is performed required times (for example, several times) to clean (brush-clean) the backside 1b of the semiconductor wafer 1. In this manner, particles attached on the backside 1b of the semiconductor wafer 1 can be mechanically removed.

During the cleaning (brush-cleaning) processing of the backside 1b of the semiconductor wafer 1 by this brush 37, a backside rinsing processing is performed on the surface (semiconductor device forming surface) 1a of the semiconductor wafer 1 directed downward. In other words, in order to prevent particles from intruding from the backside 1b of the semiconductor wafer 1, the rinsing liquid (backside rinsing liquid) 39 is supplied toward the surface 1a of the semiconductor wafer 1 from the nozzle (backside rinse nozzle) 38 disposed below the surface 1a of the semiconductor wafer 1. Supplying the rinsing liquid 39 from the nozzle 38 to the surface 1a of the semiconductor wafer 1 is continued while the backside 1b of the semiconductor wafer 1 is being cleaned (brush-cleaned) by the brush 37. The rinsing liquid 39 sprayed (ejected) from (the port 38a of) the nozzle 38 is supplied to the surface 1a of the semiconductor wafer 1 to form a liquid film on the surface 1a of the semiconductor wafer 1, and functions such that the rinsing liquid 36 supplied from the nozzle 35 to the backside 1b of the semiconductor wafer 1 does not intrude into (contact) the surface 1a of the semiconductor wafer 1. Thereby, particles removed from the backside 1b of the semiconductor wafer 1 are prevented from reattaching on the surface 1a of the semiconductor wafer 1. It is possible to prevent contamination of the surface 1a of the semiconductor wafer 1 in the step of cleaning (brush-cleaning) the backside 1b of the semiconductor wafer 1 by this backside rinsing processing for the surface 1a of the semiconductor wafer 1.

When the cleaning (brush-cleaning) of the backside 1b of the semiconductor wafer 1 by the brush 37 is terminated, the rinsing liquid 36 is supplied to the backside 1b of the semiconductor wafer 1 for a predetermined time in a state where the brush 37 is separated from the backside 1b of the semiconductor wafer 1, and the rinsing processing is performed. After this rinsing processing, spraying the rinsing liquid 36 from the nozzle 35 is stopped, and supplying the rinsing liquid 36 to the backside 1b of the semiconductor wafer 1 is terminated. At this time, spraying the rinsing liquid 39 from the nozzle 38 is also stopped, and supplying the rinsing liquid 39 to the surface 1a of the semiconductor wafer 1 is also terminated. The rotation speed of the semiconductor wafer 1 is increased as shown in the graph of FIG. 12 (increased to about 3000 rpm to 5000 rpm, for example). This can be performed by increasing the rotation speed of the spin table 33 (spin chuck 32). Thereby, the semiconductor wafer 1 is rotated at high speed, and liquid or water (the rinsing liquid 36, the rinsing liquid 39) remaining on the surface 1a and the backside 1b of the semiconductor wafer 1 is thrown off by utilizing a centrifugal force by the high-speed rotation to dry the semiconductor wafer 1. After the semiconductor wafer 1 is rotated at high speed and dried without supplying the rinsing liquid 36 and the rinsing liquid 39 for a predetermined time, the rotation of the semiconductor wafer 1 is stopped (the rotation of the spin table 33 is stopped). In this manner, after the processings in the cleaning unit 31 (cleaning processing, rinsing processing, and drying processing) are terminated and the semiconductor wafer 1 is reversed in the wafer reverse room 25 as described above, the semiconductor wafer where particles are removed from the backside 1b by brush-cleaning and which is dried thereafter is accommodated into the cassette case 22 on the load/unload portion 21 in the cleaning device again.

Next, there will be described problems caused by the backside rinsing processing in the step of cleaning the backside of the semiconductor wafer. According to the investigation by the present inventors, it is found that the following problems can occur in the backside rinsing processing in the step of cleaning the backside of the semiconductor wafer. The first problem is that breakdown (electrostatic breakdown) of a semiconductor device may occur due to static electricity at the center position of the semiconductor wafer. The second problem is that water remains on the semiconductor wafer to which the drying processing is applied so that a water mark may occur.

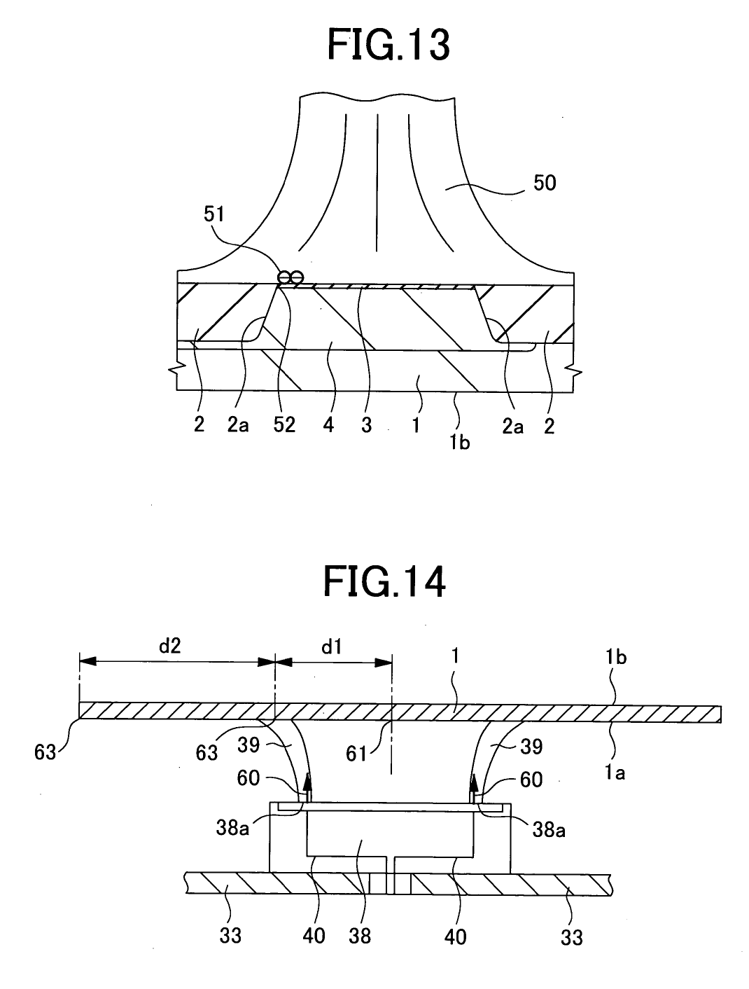

First, the first problem will be described. FIG. 13 is an explanatory diagram of electrostatic breakdown caused by the backside rinsing processing in the step of cleaning the backside of the semiconductor wafer. FIG. 13 schematically shows a state where after the structure of FIG. 3 can be obtained, when the photo lithograph pattern 5 is removed and the backside 1b of the semiconductor wafer 1 is cleaned, a rinsing liquid (backside rinsing liquid) 50 is supplied to the surface 1a of the semiconductor wafer 1. In order to facilitate understanding, in FIG. 13, a diameter of the liquid flow of the rinsing liquid 50 is shown to be smaller than actual.

According to the investigation by the present inventors, it is found that in the backside rinsing processing in the step of cleaning the backside of the semiconductor wafer performed after the isolation area 2 is formed and before the gate dielectric film 6 is formed, when the liquid flow of the rinsing liquid 50 sprayed from a nozzle (backside rinse nozzle) is fallen on the center position of the surface (semiconductor device forming surface) 1a of the semiconductor wafer 1, electrostatic breakdown is easy to occur at the edge of the isolation area 2 (isolation trench 2a). This mechanism will be described.

When the liquid flow of the rinsing liquid (backside rinsing liquid) 50 sprayed from the nozzle (backside rinse nozzle) for the backside rinsing processing is supplied to (applied to) the center position of the surface (semiconductor device forming surface) 1a of the semiconductor wafer 1, the semiconductor wafer 1 is rotated about the center position thereof so that the liquid flow of the rinsing liquid 50 is fixed on (applied to) the same position (center position) of the surface 1a of the semiconductor wafer 1 for a long time. Therefore, when the backside rinsing processing (spin rotation processing) is performed for a long time, static electricity may occur between the rinsing liquid 50 and the surface 1a of the semiconductor wafer 1 at the center position of the surface 1a of the semiconductor wafer 1 so that a dielectric film (oxide film) on the surface 1a of the semiconductor wafer 1, for example the dielectric film 3 may be charged. As a result, as shown in FIG. 13, charges 51 (for example, electrons or holes) generated on the surface of the dielectric film (oxide film) 3 concentrate on the vicinity of an edge 52 of the isolation trench 2a (isolation area 2), where electrostatic breakdown occurs.

Next, the second problem on occurrence of water mark in the semiconductor wafer will be described.

The backside rinsing processing in the step of cleaning the backside of the semiconductor wafer is performed by supplying the rinsing liquid (backside rinsing liquid) toward the surface (semiconductor device forming surface) of the semiconductor wafer directed downward from the nozzle (backside rinse nozzle) disposed below that, but when dripping of the rinsing liquid (backside rinsing liquid) occurs in the nozzle (backside rinse nozzle), the dripped rinsing liquid reaches the rotating spin table through the nozzle and is reflected (repelled) by the spin table rotating at high speed, and may attach on the surface of the semiconductor wafer. The water attached on the surface of the semiconductor wafer due to this reflection grows up to a water mark (stain generated by a water droplet remaining or attached on the surface of the cleaned and dried semiconductor wafer), and may cause machining failure in the subsequent steps. Particularly, when water is attached on the surface of the semiconductor wafer due to reflection in the stage of the drying processing, drying failure occurs so that it is likely to cause a water mark.

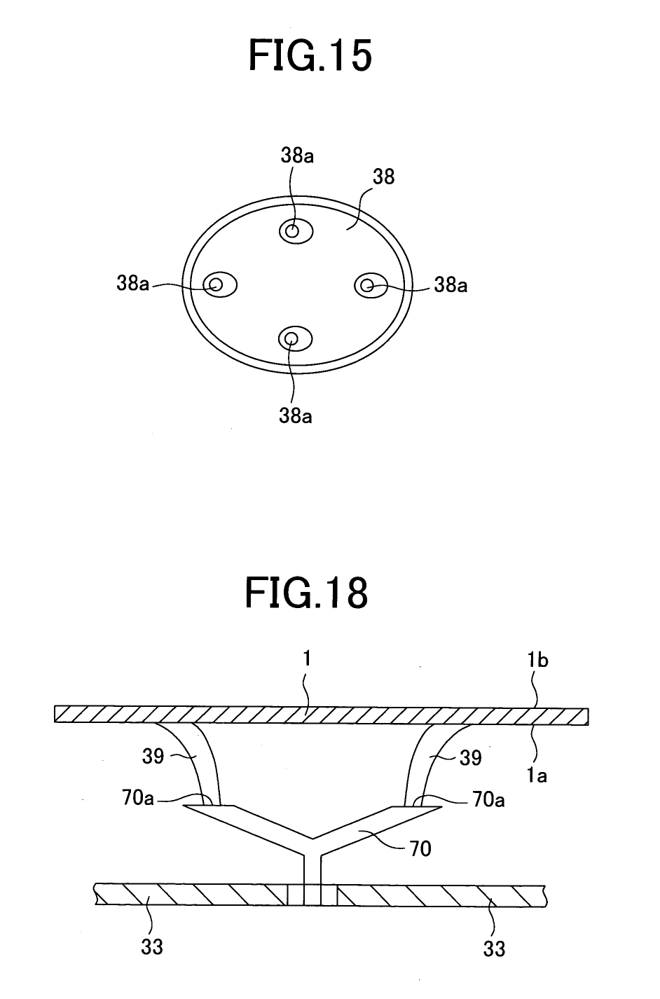

Next, the backside rinsing processing in the step of cleaning the backside of the semiconductor wafer in the present embodiment will be described in more detail. FIG. 14 is a partially enlarged view (section view) of an area in the vicinity of the nozzle 38 for the backside rinsing processing when the backside rinsing processing is performed in the cleaning unit 31 in FIG. 11, and FIG. 15 is a top view of the nozzle 38 for the backside rinsing processing.

In the present embodiment, there is constructed such that in the step of cleaning (brush-cleaning) the backside 1b of the semiconductor wafer 1, the liquid flow of the rinsing liquid 39 sprayed from (the port 38a of) the nozzle 38 is not applied to (supplied to) the center position of the surface 1a of the semiconductor wafer 1. In other words, there is constructed such that the liquid flow of the rinsing liquid 39 is applied to (supplied to) a position away from the center position of the surface 1a of the semiconductor wafer 1. Since the semiconductor wafer 1 is rotated at relatively high speed, the rinsing liquid 39 which reaches the surface 1a of the semiconductor wafer 1 is flowed in a direction of outer periphery of the surface 1a of the semiconductor wafer 1 due to a centrifugal force to form a liquid film comprised of the rinsing liquid 39 on the surface 1a of the semiconductor wafer 1. When the liquid flow of the rinsing liquid 39 sprayed from the nozzle 38 is supplied to a position away from the center position of the surface 1a of the semiconductor wafer 1 as in the present embodiment, this liquid film is formed over the entire periphery of the surface 1a of the semiconductor wafer 1, but is not formed in the vicinity of the center position of the surface 1a of the semiconductor wafer 1. Also in this case, a problem does not occur to the function of preventing particles (or the rinsing liquid 36) from intruding from the backside 1b of the semiconductor wafer 1.

In the present embodiment, since the liquid flow of the rinsing liquid 39 sprayed from the nozzle 38 is not directly applied to the center position of the surface 1a of the semiconductor wafer 1, the liquid flow of the rinsing liquid 39 is not fixed on the same position on the surface 1a of the semiconductor wafer 1 for a long time, thereby preventing a charging phenomenon of the dielectric film (dielectric film 3) on the surface 1a of the semiconductor wafer 1 as described above. Further, since the semiconductor wafer 1 is rotated, when the liquid flow of the rinsing liquid 39 sprayed from the nozzle 38 is supplied to a position away from the center position of the surface 1a of the semiconductor wafer 1 as in the present embodiment, the position on the surface 1a of the semiconductor wafer 1 on which the liquid flow of the easing liquid 39 is directly applied to is dispersed, thereby preventing a charging phenomenon of the dielectric film on the surface 1a of the semiconductor wafer 1. Thereby, it is possible to prevent electrostatic breakdown (of the semiconductor device) at the center position of the surface 1a of the semiconductor wafer 1 as described as the first problem. Therefore, it is possible to improve reliability of the semiconductor device to be manufactured and to improve manufacturing yield of the semiconductor device.

In the drying processing of the semiconductor wafer 1, water (the rinsing liquid 36, the rinsing liquid 39) remaining on the surface 1a and the backside 1b of the semiconductor wafer 1 is thrown off by utilizing the centrifugal force due to the high-speed rotation to dry the semiconductor wafer 1. At this time, it is difficult to remove the water at the center position of the semiconductor wafer 1. In the present embodiment, the liquid flow of the rinsing liquid 39 sprayed from the nozzle 38 is supplied to a position away from the center position of the surface 1a of the semiconductor wafer 1, and a liquid film for preventing particles from intruding from the backside 1a of the semiconductor wafer 1 is difficult to form in the vicinity of the center position of the surface 1a of the semiconductor wafer 1. Therefore, the water hardly remains (exists) in the vicinity of the center position of the surface 1a of the semiconductor wafer 1 at all at the stage where the drying processing is started. Thereby, the water does not remain in the vicinity of the center position of the surface 1a of the semiconductor wafer 1 at the stage where the drying is terminated, thereby preventing a water mark from occurring in the vicinity of the center position of the surface 1a of the semiconductor wafer 1 due to insufficient drying. Further, since the semiconductor device is formed on the surface 1a of the semiconductor wafer 1, the water mark on the surface 1a of the semiconductor wafer 1 may cause machining failure in the subsequent steps, but a water mark can be prevented from occurring on the surface 1a of the semiconductor wafer 1 in the present embodiment, thereby improving reliability or manufacturing yield of the semiconductor device.

A position on the surface 1a of the semiconductor wafer 1 to which the liquid flow of the rinsing liquid 39 sprayed from the nozzle 38 is applied (supplied) (position on which the center of the liquid flow of the rinsing liquid 39 is fallen) is preferably away from the center of the surface 1a of the semiconductor wafer 1 by twice or more than the diameter of the liquid flow (liquid column) of the rinsing liquid 39, more preferably away by five times or more than the diameter of the liquid flow (liquid column) of the rinsing liquid 39, and still more preferably away by seven times or more than the diameter of the liquid flow (liquid column) of the rinsing liquid 39. In other words, a distance d₁ from a center position 61 on the surface 1a of the semiconductor wafer 1 to a position 62 on the surface 1a of the semiconductor wafer 1 to which the center of the liquid flow of the rising liquid 39 is applied is preferably twice or more than the diameter of the liquid flow (liquid column) of the rinsing liquid 39, more preferably five times or more, and still more preferably seven times or more. Thereby, the position to which the liquid flow of the rinsing liquid 39 sprayed from the nozzle 38 is applied can be dispersed on the surface 1a of the semiconductor wafer 1 so that a charging phenomenon of the dielectric film (oxide film) on the surface 1a of the semiconductor wafer 1 can be prevented, thereby preventing electrostatic breakdown of the semiconductor device. The diameter of the liquid flow of the rinsing liquid 39 sprayed from the nozzle 38 substantially corresponds to the diameter of the port 38a of the nozzle 38. Further, the diameter of the liquid flow of the rinsing liquid 39 is about 2 mm, for example. In this case, the position on the surface 1a of the semiconductor wafer 1 to which the liquid flow of the rinsing liquid 39 sprayed from the nozzle 38 is applied is preferably away from the center of the surface 1a of the semiconductor wafer 1 by 4 mm or more, more preferably away by 10 mm or more, and still more preferably away by 14 mm or more. In other words, the distance d₁ from the center position 61 on the surface 1a of the semiconductor wafer 1 to the position 62 to which the center of the liquid flow of the rinsing liquid 39 is applied is preferably 4 mm or more, more preferably 10 mm or more, and still more preferably 14 mm or more.

The position on the surface 1a of the semiconductor wafer 1 to which the liquid flow of the rinsing liquid 39 sprayed from the nozzle 38 is applied (position to which the center of the liquid flow of the rinsing liquid 39 is applied) is preferably away from the outer periphery (periphery, edge) of the surface 1a of the semiconductor wafer 1 by three times or more than the diameter of the liquid flow (liquid column) of the rinsing liquid 39, and more preferably away by five times or more than the diameter of the liquid flow (liquid column) of the rinsing liquid 39. In other words, a distance d₂ from an outer peripheral (edge) position 63 on the surface 1a of the semiconductor wafer 1 to the position 62 on the surface 1a of the semiconductor wafer 1 to which the liquid flow of the rinsing liquid 39 is applied is preferably three times or more than the diameter of the liquid flow (liquid column) of the rinsing liquid 39, and more preferably five times or more. Thereby, the liquid film comprised of the rinsing liquid 39 can be accurately formed on the surface 1a of the semiconductor wafer 1, thereby securely preventing particles (or the rinsing liquid 36) from intruding from the backside 1b of the semiconductor wafer 1 into the surface 1a. When the diameter of the liquid flow of the rising liquid 39 is, for example, about 2 mm, the position on the surface 1a of the semiconductor wafer 1 to which the liquid flow of the rinsing liquid 39 sprayed from the nozzle 38 is applied is preferably away from the outer periphery of the surface 1a of the semiconductor wafer 1 by 6 mm or more, and more preferably away by 10 mm or more. In other words, the distance d₂ from the outer peripheral (edge) position 63 on the surface 1a of the semiconductor wafer 1 to the position 62 to which the center of the liquid flow of the rinsing liquid 39 is applied is preferably 6 mm or more, and more preferably 10 mm or more.

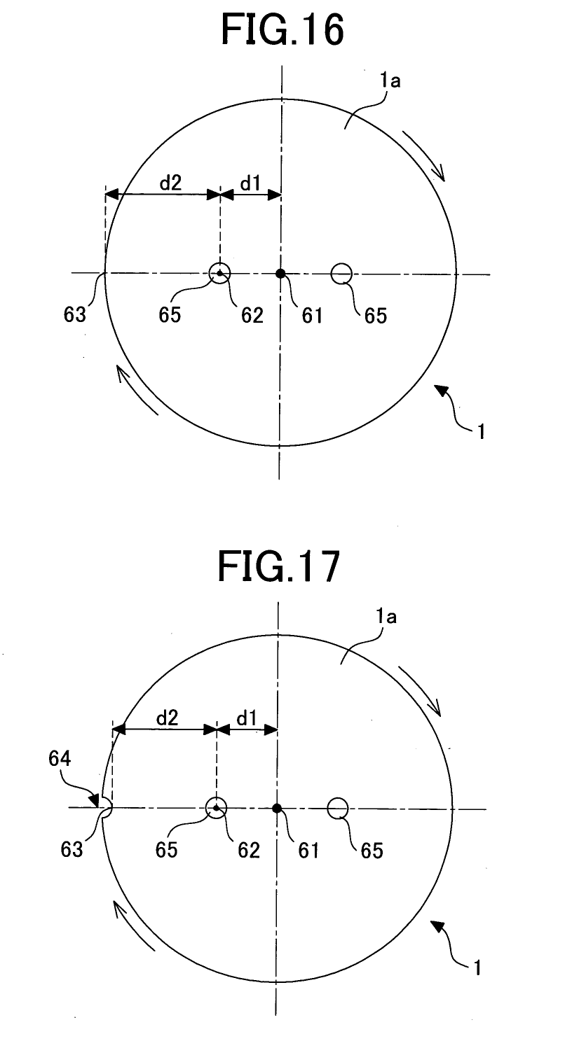

FIG. 16 and FIG. 17 are plan views for explaining a position on the surface 1a of the semiconductor wafer 1 on which the liquid flow of the rinsing liquid 39 sprayed from the nozzle 38 is fallen. FIG. 16 corresponds to a case where a plane shape of the semiconductor wafer 1 is substantially perfect circle, and FIG. 17 corresponds to a case where a notch 64 is formed on the semiconductor wafer 1. In FIG. 16 and FIG. 17, there is shown an area 65 on the surface 1a of the semiconductor wafer 1 to which the liquid flow of the rinsing liquid 39 sprayed from the nozzle 38 is directly applied, and the center of the area 65 corresponds to the position 62 to which the center of the liquid flow of the rinsing liquid 39 is applied. The semiconductor wafer 1 shown in FIG. 16 and FIG. 17 is actually rotated at high speed (about the center position 61).

As described above, the distance d₁ from the center position 61 on the surface 1a of the semiconductor wafer 1 to the position 62 to which the center of the liquid flow of the rinsing liquid 39 is applied is preferably twice or more than the diameter of the liquid flow (liquid column) of the rinsing liquid 39, more preferably five times or more, and still more preferably seven times or more. Further, the distance d₂ from the outer peripheral (edge) position 63 on the surface 1a of the semiconductor wafer 1 to the position 62 to which the center of the liquid flow of the rinsing liquid 39 is applied (distance on the line connecting the center position 61 and the position 62) is preferably three times or more than the diameter of the liquid flow (liquid column) of the rinsing liquid 39, and more preferably five times or more.

Since the semiconductor wafer 1 is rotated at high speed, an edge position nearest to the center position 61 of the surface 1a of the semiconductor wafer 1 forms the outer peripheral (edge) position 63 on the surface 1a of the rotating semiconductor wafer 1. When the plan shape of the semiconductor wafer 1 is substantially perfect circle as shown in FIG. 16 (when a notch is not formed), the distance up to the center position 61 of the surface 1a of the semiconductor wafer 1 is equal from any edge (outer peripheral edge) of the semiconductor wafer 1. However, when the notch 64 is provided on the semiconductor wafer 1 as shown in FIG. 17, the innermost position in the vicinity of the center of the notch 64 serves as the edge position nearest to the center position 61 on the surface 1a of the semiconductor wafer 1 and forms the outer peripheral (edge) position 63 on the surface 1a of the rotating semiconductor wafer 1. Therefore, even in the semiconductor wafer having the same diameter, as shown in FIG. 16 and FIG. 17, the distance d₂ from the outer peripheral (edge) position 63 on the surface 1a of the semiconductor wafer 1 is different by the notch 64 depending on whether or not the notch 64 is formed on the semiconductor wafer 1. When the notch 64 is formed on the semiconductor wafer 1, as shown in FIG. 17, the distance d₂ from the edge position nearest to the center position 61 on the surface 1a of the semiconductor wafer 1 (the innermost position of the notch 64) to the position 62 to which the center of the liquid flow of the rinsing liquid 39 is applied is set to be preferably three times or more than the diameter of the liquid flow (liquid column) of the rinsing liquid 39, and more preferably five times or more, so that the liquid film comprised of the rinsing liquid 39 can be accurately formed on the surface 1a of the semiconductor wafer 1 without influence due to the notch 64, thereby securely preventing particles (or the rinsing liquid 36) from intruding from the backside 1b of the semiconductor wafer 1 to the surface 1a. This is applied to a case where not the notch 64 but an orientation flat is provided on the semiconductor wafer 1, and the edge position nearest to the center position 61 on the surface 1a of the semiconductor wafer 1 (for example, the center position of the orientation flat) corresponds to the outer peripheral (edge) position 63 on the surface 1a of the rotating semiconductor wafer 1.

In the present embodiment, in the step of cleaning (brush-cleaning) the backside 1b of the semiconductor wafer 1, the rinsing liquid 39 is sprayed in a vertical direction toward the surface 1a of the semiconductor wafer 1 from (the port 38a of) the nozzle 38. In other words, a direction of spray 60 of the rinsing liquid 39 from the nozzle 38 is set to be orthogonal to the surface 1a of the semiconductor wafer 1. When the direction of spray 60 of the rinsing liquid 39 from the nozzle 38 is oblique with respect to the surface 1a of the semiconductor wafer 1, there is a fear that the aforementioned second problem may occur. In other words, when spraying the rinsing liquid 39 is stopped in order to enter the drying processing, the rinsing liquid 39 drops outside the port 38a, which causes dripping on the upper surface of the nozzle 38. This dripped rinsing liquid 39 reaches the spin table 33 through the upper surface of the nozzle 38 in the stage of the drying processing is reflected (repelled) by the spin table 33 rotating at high speed, so that the rinsing liquid 39 may be attached on the surface 1a of the semiconductor wafer 1. When this occurs in the end of the drying processing of the semiconductor wafer 1, there is a possibility that the drying processing of the semiconductor wafer 1 is terminated before water (the rinsing liquid 39) attached on the surface 1a of the semiconductor wafer 1 due to reflection from the spin table 33 is not perfectly removed. Further, when the water (the rinsing liquid 39) is attached in the vicinity of the center of the surface 1a of the semiconductor wafer 1 due to reflection from the spin table 33, the water is not easy to remove.

In the present embodiment, since the direction of spray 60 of the rinsing liquid 39 from (the port 38a of) the nozzle 38 is set to be orthogonal to the surface 1a of the semiconductor wafer 1, even if spraying the rinsing liquid 39 from (the port 38a of) the nozzle 38 is stopped when the backside rinsing processing is terminated to proceed to the drying processing, the rinsing liquid 39 returns to the port 38a. Thus, the rinsing liquid 39 does not drop outside the port 38a on the upper surface of the nozzle 38 so that dripping does not occur in the nozzle 38. Further, when spraying the rinsing liquid 39 is stopped, it is more preferable that an operation of sucking (introducing) the rinsing liquid 39 from the port 38a is performed by using a suck-back system, for example. Thereby, the rinsing liquid 39 returned to the port 38a of the nozzle 38 can be collected into the port 38a and the rinsing liquid 39 which dropped in the vicinity of the port 38a on the upper surface of the nozzle 38 can be collected into the port 38a. Thus, after spraying the rinsing liquid 39 from the nozzle 38 is stopped, the rinsing liquid 39 is not present on the upper surface of the nozzle 38 so that dripping does not occur in the nozzle 38. Therefore, the rinsing liquid 39 moved on the upper surface of the nozzle 38 is not reflected by the spin table 33 and is not attached on the surface 1a of the semiconductor wafer 1 in the drying stage of the semiconductor wafer 1. Thereby, it is possible to prevent drying failure on the surface 1a of the semiconductor wafer 1 and to prevent a water mark from occurring. Further, machining failure due to the water mark does not also occur, thereby improving reliability of the semiconductor device and improving manufacturing yield of the semiconductor device.

The direction of spray 60 of the rinsing liquid 39 from the nozzle 38 is orthogonal to the surface 1a of the semiconductor wafer 1 as described above, but particularly the direction of spray 60 of the rinsing liquid 39 from the nozzle 38 is preferably within a range of 80 to 90 degrees relative to the surface 1a of the semiconductor wafer 1 (a tilt relative to 90 degrees is within 10 degrees), and the direction of spray 60 of the rinsing liquid 39 from the nozzle 38 is more preferably within a range of 85 to 90 degrees relative to the surface 1a of the semiconductor wafer 1 (a tile relative to 90 degrees is within 5 degrees). If the direction of spray 60 of the rinsing liquid 39 is within 80 to 90 degrees relative to the surface 1a of the semiconductor wafer 1, a considerable amount of the rinsing liquid 39 can be collected into the port 38a when spaying the rinsing liquid 39 is stopped, and if the direction of spray 60 of the rinsing liquid 39 is within 85 to 90 degrees relative to the surface 1a of the semiconductor wafer 1, the rinsing liquid 39 can be almost collected into the port 38a. Thereby, it is possible to more accurately prevent the rinsing liquid 39 from attaching on the surface 1a of the semiconductor wafer 1 in the drying stage. Therefore, it is possible to more securely prevent drying failure or water mark from occurring in the semiconductor wafer 1.

In the present embodiment, as shown in FIGS. 14 and 15, in the nozzle 38, the port 38a is not provided at the position corresponding to a position immediately below the center on the surface 1a of the semiconductor wafer 1 (the center position on the upper surface of the nozzle 38, for example), but is provided away therefrom so that the rinsing liquid 39 is sprayed in a vertical direction relative to the surface 1a of the semiconductor wafer 1. In this manner, the liquid flow of the rinsing liquid 39 is supplied to the position away from the center of the surface 1a of the semiconductor wafer 1, thereby preventing electrostatic breakdown of the semiconductor device in the semiconductor wafer 1, and the rinsing liquid 39 is sprayed in a vertical direction relative to the surface 1a of the semiconductor wafer 1 from the nozzle 38, thereby preventing dripping in the nozzle 38 and preventing drying failure or water mark from occurring in the semiconductor wafer 1.

As shown in FIGS. 14 and 15, it is also possible to provide a plurality of ports 38a in the nozzle 38. Thereby, the rinsing liquid 39 can be supplied to the surface 1a of the semiconductor wafer 1 from a plurality of ports 38a of the nozzle 38 (multidirectionally) so that the positions on the surface 1a of the semiconductor wafer 1 to which the liquid flows of the rinsing liquid 39 are applied can be dispersed. Therefore, concentration of charges due to charging of the dielectric film on the surface 1a of the semiconductor wafer 1 can be alleviated, thereby more accurately preventing electrostatic breakdown.

FIG. 18 is an explanatory diagram of a nozzle (backside rinse nozzle) 70 for the backside rinsing processing according to another embodiment and shows a case where the nozzle 70 is used instead of the nozzle 38 in FIG. 14.

As shown in FIG. 18, there can be employed the nozzle (backside rinse nozzle) 70 having a structure where a port (rinse port, rinsing liquid spray port) 70a for supplying the rinsing liquid 39 is directed toward the surface 1a of the semiconductor wafer 1. Also in this case, the liquid flow of the rinsing liquid 39 sprayed from the port 70a of the nozzle 70 is supplied to a position away from the center of the surface 1a of the semiconductor wafer 1, thereby preventing electrostatic breakdown of the semiconductor device in the semiconductor wafer 1. Further, the direction of spray of the rinsing liquid 39 from the port 70a of the nozzle 70 is set to be orthogonal to the surface 1a of the semiconductor wafer 1, thereby preventing dripping in the nozzle 70 and preventing drying failure or water mark from occurring in the surface 1a of the semiconductor wafer 1.

In the present embodiment, the position of the nozzle 38 is fixed, and the rinsing liquid 39 is supplied from the port 38a at the same position to the surface 1a of the rotating semiconductor wafer 1. As other embodiment, the rinsing liquid 39 may be sprayed while rotating the nozzle 38. For example, the position of the nozzle 38 is moved or rotated in a horizontal direction, in a vertical direction, in an oblique direction, or in a combination thereof so that the position of the port 38a is changed with time and the rinsing liquid 39 is sprayed from various positions. Thereby, the position to which the liquid flow of the rinsing liquid 39 sprayed from the nozzle 38 is applied is not fixed on the same position on the surface 1a of the semiconductor wafer 1 and is further dispersed, thereby more securely preventing electrostatic breakdown in the semiconductor wafer 1. Further, when the nozzle 38 is fixed, a system for moving or rotating the nozzle 38 is not required so that the structure of the cleaning device can be further simplified.

In the cleaning step performed after the isolation area 2 is formed on the semiconductor wafer 1 and before the gate dielectric film 6 is formed, it is more preferable that the step (step S4) of cleaning the backside of the semiconductor wafer as in the present embodiment described above is performed. According to the investigation by the present inventors, at the stage after the isolation area 2 is formed on the semiconductor wafer 1 and before the gate dielectric film 6 is formed, charging of the dielectric film (for example, the dielectric film 3) or electrostatic breakdown is likely to occur due to the fact that the liquid flow of the rinsing liquid (backside rinsing liquid) sprayed from the nozzle for the backside rinsing processing is applied to the same position on the surface 1a of the semiconductor wafer 1 for a long time. In the present embodiment, in the cleaning step (of cleaning the backside of the semiconductor wafer) performed after the isolation area 2 is formed on the semiconductor wafer 1 where electrostatic breakdown is likely to occur and before the gate dielectric film 6 is formed, the liquid flow of the rinsing liquid 39 sprayed from the nozzle 38 is fallen on (supplied to) a position away from the center of the surface 1a of the semiconductor wafer 1, thereby preventing the dielectric film from charging in (the vicinity of the center of) the surface 1a of the semiconductor wafer 1 and accurately preventing electrostatic breakdown of the semiconductor device.

In the stage after the isolation area 2 is formed on the semiconductor wafer 1 and before the gate dielectric film 6 is formed, it is more preferable that the cleaning step (of cleaning the backside of the semiconductor wafer) as in the present embodiment described above is performed before thermal diffusion (for example, step S6). For example, the cleaning step as in the present embodiment is performed after impurities are ion-implanted into the semiconductor wafer 1 and before thermal diffusion for diffusing (or activating) the introduced impurities is performed. When particles are attached on the semiconductor wafer, there is a fear that metals in the particles are diffused into the semiconductor wafer by the thermal diffusion, which lowers performance of the semiconductor to be manufactured. The step of cleaning the backside on the semiconductor wafer as in the present embodiment is performed before the thermal diffusion, thereby removing particles attached on the semiconductor wafer 1 and improving performance of the semiconductor device to be manufactured.

In the present embodiment, it is more preferable that the step of cleaning the backside of the semiconductor wafer 1 is performed before the wet-cleaning processing, particularly before the butch type wet-cleaning processing. Thereby, the wet-cleaning processing can be performed after particles on the backside 1b of the semiconductor wafer 1 are previously removed, thereby reducing contamination of a liquid bath of the wet-cleaning device. It is possible to prevent contamination (particles) on the backside 1b of the semiconductor wafer 1 from diffusing to contaminate the surface of the semiconductor wafer. Further, it is possible to more accurately prevent mutual contamination between the semiconductor wafers in the butch type wet-cleaning processing (device). Particles which are difficult to remove by the wet-cleaning processing can be mechanically removed in the step of cleaning the backside of the semiconductor wafer in the present embodiment, thereby further improving cleanness of the semiconductor wafer.

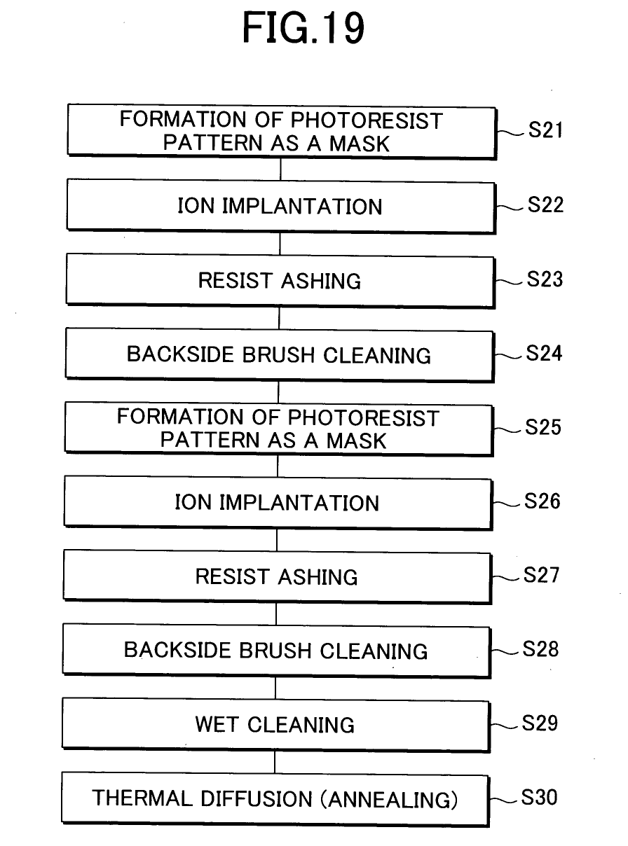

It is more preferable that the step of cleaning the backside of the semiconductor wafer as in the present embodiment described above is performed before the photo lithography step (step of forming the photo lithograph pattern) in the stage after the isolation area 2 is formed on the semiconductor wafer 1 and before the gate dielectric film 6 is formed. FIG. 19 is a flow chart for explaining the steps from ion implantation to thermal diffusion for forming the p-type well 4 according to another embodiment. FIG. 19 corresponds to a case where ion implantation is performed twice by changing an accelerator energy of the ion implantation in order to change or adjust a concentration profile (distribution) of the impurities in the p-type well 4, for example.

As shown in FIG. 19, a photo lithograph pattern (photo resist mask, photo resist pattern) is formed on the surface 1a of the semiconductor wafer 1 (step S21), and the first ion implantation is performed by using this photo lithograph pattern as a mask (step S22). Then, the photo lithograph pattern is removed by the ashing processing (step S23). The brush-cleaning described above is performed for the backside 1b of the semiconductor wafer 1 as in the above step S4 (step S24). Thereafter, another photo lithograph pattern (photo resist mask, photo resist pattern) is formed on the surface 1a of the semiconductor wafer 1 (step S25), and the second ion implantation is performed by using this photo lithograph pattern as a mask (step S26). Then, the photo lithograph pattern is removed by the ashing processing (step S27), and the brush-cleaning described above is performed for the backside 1b of the semiconductor wafer 1 as in the above step S4 (step S28). Thereafter, the wet-cleaning is performed by the wet-cleaning device (step S29). Then, thermal diffusion is performed to diffuse or activate the impurities introduced (ion-implanted) into the semiconductor wafer 1 (step S30). Thereby, the p-type well 4 having a desired concentration profile of impurities can be formed.

When the next photo lithography step (step S25) is performed without performing the step of cleaning the backside of the semiconductor wafer (step S24) after the photo lithograph pattern is removed by ashing (step S23), defocus occurs in the photo lithography step when a large amount of particles are attached on the backside of the semiconductor wafer, and there is a fear that accuracy of the photo lithograph pattern to be formed is lowered. The step of cleaning the backside of the semiconductor wafer as in the present embodiment is performed before the photo lithography step (step S25) so that the photo lithography step can be performed in a state where particles attached on the backside of the semiconductor wafer are removed, thereby improving accuracy of the photo lithograph pattern to be formed.

In the present embodiment, pure water can be employed as the rinsing liquid 39. A cost for manufacturing the semiconductor device can be reduced by using pure water. Further, even when cleaning is performed in a state where a metal material film is formed on the semiconductor wafer 1, the metal material film is prevented from corroding. As other embodiment, pure water where carbon dioxide (CO₂) is dissolved can be used as the rinsing liquid 39 as a measurement for static electricity. Thereby, it is possible to more accurately restrict occurrence of static electricity in the semiconductor wafer 1 and to more securely prevent occurrence of electrostatic breakdown. Further, since pure water where carbon dioxide (CO₂) is dissolved shifts the water quality to acidic, it is preferable that it is used as the rinsing liquid for the backside rinsing processing in the step of cleaning the backside of the semiconductor wafer at the stage where the metal material film is not exposed (before the metal material film is formed). Thus, it is possible to prevent corrosion of the metal material film.

Further, in the present embodiment, the brush-cleaning (scrub-cleaning) system for performing (mechanical) cleaning by the brush 37 is used as the system of cleaning the backside 1b of the semiconductor wafer 1. Thus, a capability of removing particles attached on the backside 1b of the semiconductor wafer 1 can be remarkably increased. As other embodiment, the cleaning of the backside 1b of the semiconductor wafer 1 can be performed by other cleaning system, for example, a jet-cleaning system (of supplying the rinsing liquid (cleaning liquid) to the backside 1b of the semiconductor wafer 1 by strong eject) or an ultrasonic wave cleaning system (of applying ultrasonic wave to the rinsing liquid (cleaning liquid) to be supplied to the backside 1b of the semiconductor wafer 1 and supplying the same). When the jet-cleaning system or the ultrasonic wave cleaning system is used, particles can be removed in a non-contact manner for the backside 1b of the semiconductor wafer 1. Thus, it is possible to remove only contamination such as particles without adversely affecting the semiconductor wafer 1. Even when the jet-cleaning system or the ultrasonic wave cleaning system is used to clean the backside 1b of the semiconductor wafer 1, it is possible to obtain a similar effect by similarly performing the backside rinsing processing for the backside 1b of the semiconductor wafer 1 as in the present embodiment, thereby preventing electrostatic breakdown or water mark from occurring in the surface 1a of the semiconductor wafer 1, for example.

Hereinbefore, the invention made by the present inventors is specifically described on the basis of the embodiments, but the present invention is not limited to the above embodiments, and it goes without saying that various modifications can be made within the range without departing from the spirit.

In the above embodiments, the steps of manufacturing the semiconductor device having the MISFET are described, but the present invention is not limited thereto, and can be applied to various semiconductor devices.

The effects obtained from the representative inventions among the inventions disclosed in this application will be simply described as follows.

When cleaning the backside of the semiconductor wafer, the rinsing liquid is supplied to a position away from the center of the surface of the semiconductor wafer, thereby preventing electrostatic breakdown from occurring in the semiconductor wafer.

When cleaning the backside of the semiconductor wafer, the direction of spray of the rinsing liquid from the rinsing liquid supplying means for supplying the rinsing liquid to the surface of the semiconductor wafer is set to be orthogonal to the surface of the semiconductor wafer, thereby preventing drying failure in the semiconductor wafer.

What is claimed is:

1. A method of manufacturing a semiconductor device comprising a step of cleaning a backside of a semiconductor wafer while rotating said semiconductor wafer in a state where said backside of said semiconductor wafer is directed upward,
wherein, in the step of cleaning a backside of a semiconductor wafer, a rinsing liquid is sprayed in a vertical direction relative to a surface of said semiconductor wafer from rinsing liquid supplying nozzles disposed below said surface of said semiconductor wafer, and a liquid flow of said rising liquid sprayed from said rinsing liquid supplying nozzles is supplied to a position away from the center of said surface of said semiconductor wafer.

2. The method of manufacturing a semiconductor device according to claim 1, wherein said backside of said semiconductor wafer is applied to brush-cleaning.

3. The method of manufacturing a semiconductor device according to claim 1, wherein said backside of said semiconductor wafer is applied to jet-cleaning or ultrasonic wave cleaning.

4. The method of manufacturing a semiconductor device according to claim 1, wherein a direction of spray of a rinsing liquid from said rising liquid supplying nozzles is within a range of 80 to 90 degrees relative to said surface of said semiconductor wafer.

5. The method of manufacturing a semiconductor device according to claim 1, wherein a direction of spray of a rinsing liquid from said rinsing liquid supplying nozzles is within a range of 85 to 90 degrees relative to said surface of said semiconductor wafer.

6. The method of manufacturing a semiconductor device according to claim 1, wherein a liquid flow of said rinsing liquid sprayed from said rinsing liquid supplying nozzles is supplied to a position away from said center position of said surface of said semiconductor wafer by twice or more than the diameter of said liquid flow of said rinsing liquid.

7. The method of manufacturing a semiconductor device according to claim 1, wherein a liquid flow of said rinsing liquid sprayed from said rising liquid supplying nozzles is supplied to a position away from the center position of said surface of said semiconductor wafer by five times or more than the diameter of said liquid flow of said rising liquid.

8. The method of manufacturing a semiconductor device according to claim 1, wherein a liquid flow of said rising liquid sprayed from said rising liquid supplying nozzles is supplied to a position inner than the peripheral position of said semiconductor wafer by three times or more than the diameter of said liquid flow of said rinsing liquid.

9. A method of manufacturing a semiconductor device comprising the steps of:
(a) preparing a semiconductor wafer;
(b) forming an isolation area on a surface of said semiconductor wafer;
(c) cleaning a backside of said semiconductor wafer while rotating said semiconductor wafer in a state where said backside of said semiconductor wafer is directed upward after the step (b); and
(d) forming a gate dielectric film on said surface of said semiconductor wafer after the step (c),
wherein, in the step (c), a rinsing liquid is sprayed to said surface of said semiconductor wafer from rinsing liquid supplying means disposed below said surface of said semiconductor wafer, and a liquid flow of said rising liquid sprayed from said rinsing liquid supplying means is supplied to a position away from the center of said surface of said semiconductor wafer.

10. The method of manufacturing a semiconductor device according to claim 9, wherein said rinsing liquid supplying means is comprised of a nozzle, and a liquid flow of said rising liquid sprayed from said nozzle is directly supplied to said surface of said semiconductor wafer in the step (c).

11. The method of manufacturing a semiconductor device according to claim 9, wherein said rising liquid supplying means has a plurality of ports for spraying said rinsing liquid, and liquid flows of said rising liquid sprayed from said plurality of ports are supplied to positions away from the center of said surface of said semiconductor wafer, respectively, in the step (c).

12. The method of manufacturing a semiconductor device according to claim 9, wherein said rising liquid supplying means sprays said rinsing liquid while moving in the step (c).

13. The method of manufacturing a semiconductor device according to claim 9, further comprising a step of wet-cleaning said semiconductor wafer after the step (c) and before the step (d).

14. The method of manufacturing a semiconductor device according to claim 9, further comprising a step of thermally diffusing said semiconductor wafer after the step (c) and before the step (d).

15. The method of manufacturing a semiconductor device according to claim 9, further comprising a step of forming a photo lithograph pattern on said surface of said semiconductor wafer after the step (c) and before the step (d).
